(19) United States
(12) Patent Application Publication
(10) Pub. No.: US 2019/0098760 A1
(43) Pub. Date: Mar. 28, 2019

(54) EXOTHERMIC REACTION ELECTRODE STRUCTURE USING PCB AND SEMICONDUCTOR FABRICATION METHODS

(71) Applicant: IH IP Holdings Limited, Raleigh, NC (US)

(72) Inventors: Joseph A. Murray, Raleigh, NC (US); Julie A. Morris, Flower Mound, TX (US); Tushar Tank, Raleigh, NC (US)

(21) Appl. No.: 16/204,162

(22) Filed: Nov. 29, 2018

Related U.S. Application Data
(63) Continuation of application No. PCT/US18/38163, filed on Jun. 19, 2018.
(60) Provisional application No. 62/521,581, filed on Jun. 19, 2017.

(51) Int. Cl. H05K 1/16; H05K 3/46; H01L 21/48; H01G 9/042

(52) U.S. Cl. CPC H05K 1/162; H05K 3/4644; H05K 2201/0183; H01G 9/042; H01L 21/4857

(57) ABSTRACT

Printed circuit board and/or semiconductor wafer fabrication techniques and technologies are applied to create anode and cathode electrodes for exothermic reaction chambers and processes. Starting with an appropriate substrate, e.g., ceramic, anodes and cathodes of varying shapes and spaced relationships, formed of the reactive materials required, may be fabricated on the same or different layers as conductive traces. In some embodiments, the shapes and placement of the traces, and use of one or more ground planes, may optimize the generation of magnetic fields as current passes through the traces. In some embodiments, an iron core may shape and/or enhance the strength of magnetic fields. In general, the use of PCB/IC fabrication technology allows the manufacture of electrodes for exothermic reactions that are rugged, made from appropriate materials, and have known and repeatable impedances, spaced relationships, magnetic coupling, and other properties.

### CROSS-REFERENCE TO RELATED APPLICATION

This application is a continuation of PCT Patent Application No. PCT/US2018/038163 entitled “ EXOTHERMIC REACTION ELECTRODE STRUCTURE USING PCB AND SEMICONDUCTOR FABRICATION METHODS,” (Attorney Docket No. 438/27 PCT) which was filed on Jun. 19, 2018, which claims benefit of and priority to U.S. Provisional Patent Application No. 62/521,581 entitled “ EXOTHERMIC REACTION ELECTRODE STRUCTURE USING PCB AND SEMICONDUCTOR FABRICATION METHODS,” (Attorney Docket No. 438/27/2 PROV) which was filed on Jun. 19, 2017, the contents of both of which are incorporated by reference herein.

### FIELD OF INVENTION

The present invention relates generally to exothermic reactions, and in particular to the formation of electrodes optimized for use in exothermic reactions utilizing principles and techniques from printed circuit board and semiconductor fabrication processes.

### BACKGROUND

Some electrolysis reactions are known to generate anomalous heat—that is, heat that cannot be accounted for by chemical reactions of the reagents and the energy input to the reaction. These are referred to herein as “exothermic reactions.” There are generally three types of electrolysis reactions of interest in the study of exothermic reactions: wet cell, dry cell (also known as gas cell), and plasma cell. In wet cell reactions, electrical current is passed between an anode and cathode in the presence of interstitial liquid, such as heavy water (deuterium oxide). The electrolysis separates H₂ or D₂ from O₂, and loads the former into a metal or alloy lattice. In this case, an effective configuration of electrodes is to form one electrode as a coil around another electrode. In a dry/gas cell reaction, an anode and cathode may be placed in various spaced-apart configurations, with interstitial hydrogen or deuterium gas (or a vacuum). Magnetic fields may be useful in triggering exothermic reactions in dry/gas cell reactions. In a plasma cell reaction, an anode may be centrally located in a reaction chamber, with a metal or alloy plated on the chamber walls serving as a cathode. A high voltage signal applied to the anode generates a plasma discharge between the anode and cathode, accelerating hydrogen or deuterium ions into the latter.

In all three environments, it is believed that properties of the anode and/or cathode—such as material, size, shape, electrical resistivity, magnetic permeability, and the like—as well as the physical positioning and relationship of the anode and/or cathode (e.g., to generate and enhance magnetic fields or plasma formation), may be critical to triggering and/or sustaining an exothermic reaction. Currently, the material, formation, shaping, and placement of these electrodes are some of the many variables manipulated by researchers exploring the field.

The current known techniques for creating electrodes used to trigger an exothermic reaction are not easily manufactured. Most exothermic reaction chambers require the same basic elements: a first electrode made of a transition metal, such as palladium or nickel; a second electrode made of a rugged metal, such as platinum or molybdenum; a substrate, such as gold or ceramic; and a working fluid or media, such as heavy water or deuterium gas. The electrodes have a physical relationship, based on geometry and impedance, so that various triggering methods may be induced. Triggering methods may include running high voltage and low current across the electrodes, or running current to induce a specific magnetic field or plasma discharge. The ability to induce a current is also dependent on the working fluid which creates a path for current flow between the electrodes. The substrate is also important, as it helps to control the impedance between the electrodes and where the current flows. The substrate and working fluid may also be important to help provide additional required materials such as hydrogen or deuterium.

As exothermic reaction triggering methods and the materials required to cause and sustain them are better understood, and as the field transitions from an area of scientific research to the production of useful energy sources, electrodes having precisely controlled properties will be required in high volume. It is not anticipated that the current state of the art in designing, building, and deploying the electrodes required for exothermic reactions will meet the challenges of precise, repeatable design and quality control required for mass production.

As one example, in some wet cell reaction chambers, it is known to place the two electrodes in a liquid, such as heavy water, where one electrode is suspended in the solution and the other electrode is made into a coil around the first electrode. This configuration makes the system fragile and difficult to manufacture.

In the electronic arts, the reliable creation of precise circuit patterns has been practiced for decades, such as to build printed circuit boards (PCB), and semiconductor wafers from which individual integrated circuits (IC) are cut. In PCB fabrication, for example, a dielectric substrate, such as FR-4 (a glass epoxy) has copper foil laminated on one or both sides. A mask defining the desired conductive traces is applied over the copper, and the board is exposed to intense light or chemicals to etch away the copper, except that under the mask. The mask is then removed, and if desired, a dielectric layer applied over the traces. The process is repeated to build up multi-layer PCBs (with traces on different layers electrically connected by vias, or holes filled with a conductor such as solder). In the case of ICs, a semiconductor wafer such as silicon may be “doped” by techniques such as diffusion and ion implantation to create areas having desired physical and electrical properties. Similar photo-lithographic techniques are then used to build conductive traces connecting these areas, to build and interconnect circuit components such as transistors. In both applications—PCB and IC fabrication—the materials, processes, design and production techniques, fabrication equipment, and the like, are well known and readily available. However, these techniques have never been applied to the fabrication of electrodes for exothermic reactions, which have numerous specific environmental and operational requirements that likely preclude the use of conventional, off-the-shelf PCB/IC materials and processes (e.g., the ability to withstand very high temperatures).

The Background section of this document is provided to place embodiments of the present invention in technological and operational context, to assist those of skill in the art in understanding their scope and utility. Unless explicitly identified as such, no statement herein is admitted to be prior art merely by its inclusion in the Background section.

### SUMMARY

The following presents a simplified summary of the disclosure in order to provide a basic understanding to those of skill in the art. This summary is not an extensive overview of the disclosure and is not intended to identify key/critical elements of embodiments of the invention or to delineate the scope of the invention. The sole purpose of this summary is to present some concepts disclosed herein in a simplified form as a prelude to the more detailed description that is presented later.

According to one or more embodiments described and claimed herein, PCB and/or semiconductor wafer fabrication concepts and techniques are applied to create anode and cathode electrodes for exothermic reaction chambers and processes, referred to herein (without loss of generality) as a “PCB-type exothermic reaction electrode structure.” Starting with an appropriate substrate, e.g., ceramic, anodes and cathodes of varying shapes and spacings may be fabricated on the same or different layers as conductive traces. In some embodiments, the shapes and placement of the traces may optimize the generation of magnetic fields as current passes through the traces. In some embodiments, an iron core may shape and/or enhance the strength of magnetic fields. In general, the use of PCB/IC fabrication technology allows the creation of anodes and cathodes for exothermic reaction chambers having known impedances and being made of known metals. It allows the application of conductive traces to a substrate in patterns conducive to creating desired magnetic fields when current is directed through the traces. In this manner, anodes and cathodes can be designed and optimized for individual exothermic reaction chambers, and they can be manufactured in high volume with good quality control and repeatability.

One embodiment relates to an electrode structure for exothermic reactions. The electrode structure includes a core dielectric or semiconductor substrate. The structure additionally includes a first electrode comprising a first electrode material deposited on a first dielectric or semiconductor substrate surface. The first material comprises palladium, nickel, or an alloy of palladium and nickel. The structure further includes a second substrate comprising a second electrode material deposited on a second dielectric or semiconductor substrate surface.

Another embodiment relates to a method of fabricating an electrode structure. A core dielectric or semiconductor substrate is provided. A first electrode is formed as a pattern of a first electrode material comprising nickel or palladium or an alloy of nickel and palladium. The first electrode is formed on a first dielectric or semiconductor substrate surface. A second electrode is formed as a pattern of a second electrode material formed on a second dielectric or semiconductor substrate surface.

Yet another embodiment relates to an exothermic reaction chamber. The exothermic reaction chamber includes an anode connected to a first power supply terminal; a cathode connected to a second power supply terminal; and a housing comprising the anode, cathode, and optionally an interstitial fluid. At least one of the anode and cathode comprises a first electrically conductive trace on a dielectric or semiconductor substrate. One of a current between the anode and cathode, and a magnetic field generated by the anode, the cathode, or both, is operative to trigger or control an exothermic reaction in the exothermic reaction chamber.

### BRIEF DESCRIPTION OF THE DRAWINGS

The present invention will now be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. Like numbers refer to like elements throughout.

FIG. 1 is an exploded-layer perspective depiction of one processes of fabricating a PCT-type exothermic reaction electrode structure.

FIG. 2 is a perspective view of a PCB-type exothermic reaction electrode structure having two electrodes formed on the same trace layer.

FIG. 3 is a perspective view of a PCB-type exothermic reaction electrode structure having two electrodes formed on different trace layers.

FIG. 4 is a section view of a PCB-type exothermic reaction electrode structure in a wet cell reaction chamber.

FIG. 5 is a section view of a PCB-type exothermic reaction electrode structure in a dry/gas or plasma cell reaction chamber.

FIG. 6 is a section view of a PCB-type exothermic reaction electrode structure having two electrodes formed on the same trace layer, showing a magnetic field.

FIG. 7 is a section view of a PCB-type exothermic reaction electrode structure having two electrodes formed on different trace layers, showing a magnetic field.

FIG. 8 is a perspective view of a PCB-type exothermic reaction electrode structure having two electrodes formed on different trace layers in an antenna pattern, showing a magnetic field.

FIG. 9 is a perspective view of a PCB-type exothermic reaction electrode structure having two electrodes formed on different trace layers in an antenna pattern with a magnetic core and wire magnetic field guide, showing a magnetic field.

### DETAILED DESCRIPTION

For simplicity and illustrative purposes, the present invention is described by referring mainly to an exemplary embodiment thereof. In the following description, numerous specific details are set forth in order to provide a thorough understanding of the present invention. However, it will be readily apparent to one of ordinary skill in the art that the present invention may be practiced without limitation to these specific details. In this description, well known methods and structures have not been described in detail so as not to unnecessarily obscure the present invention.

Embodiments of the present invention use lithography techniques similar to those used for building PCBs, and apply similar manufacturing techniques to building electrodes, substrate, and triggering mechanisms required for exothermic reactions. General considerations relating to the fabrication of PCB-type exothermic reaction electrode structures are discussed below, followed by detailed discussion of specific requirements related to each of three types of exothermic reactions: wet cell, dry/gas cell, and plasma cell.

### PCB-type Exothermic Reaction Electrode Structures

Although the techniques are borrowed from PCB fabrication, the design and manufacture of electrodes for exothermic reactions are significantly different for several reasons. One or more metal or alloy conductors are used to form the electrode traces, since the first and second electrodes may need to be different materials. There are at least two methods for forming the electrodes.

In the first method, an electrode is formed as a sheet of conductive material with the appropriate thickness and other properties. In some embodiments, the conductive material may be applied in an atmosphere of D₂ or H₂ to support co-deposition during manufacture. Additionally, this may avoid contamination of the conductive material with trapped O₂ or other unwanted molecules. A mask is then applied to define the trace pattern, and non-masked areas are etched away from the electrode sheet (e.g., by chemical etching, laser, or the like), leaving the desired trace patterns.

In the second method, a negative of the trace mask is initially applied, and then the electrode material is applied only to the non-masked areas the substrate. In this method, less electrode material is used.

In either case, the electrode material must be controlled closely to achieve the appropriate percent material for a desired alloy. Also, in either method, other materials, such as gold or copper, may need to be applied over the substrate before applying the electrode material.

In either case, substrate material is carefully selected as well. In one embodiment, ceramic is used, to withstand high temperatures and be non-conductive. In some embodiments, materials different than the typical FR4 that is used in PCBs are used, since the environment for exothermic reactions is dramatically different than that for typical PCB uses, for which the maximum expected temperature is 100° C.

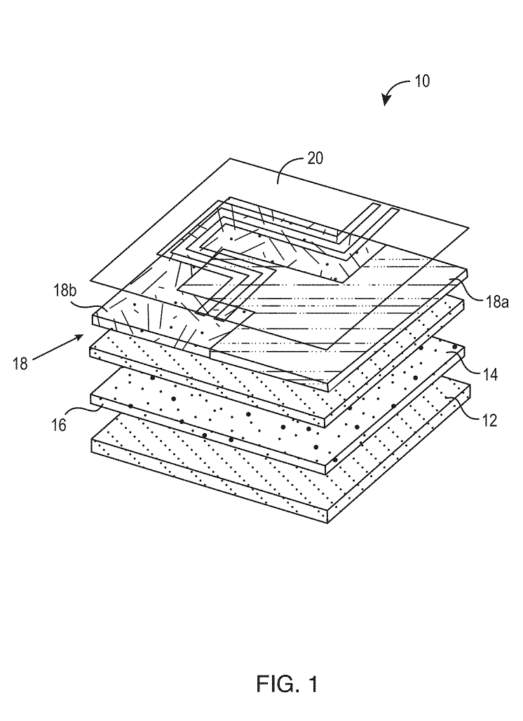

FIG. 1 depicts an exploded diagram of a PCB-type exothermic reaction electrode structure 10. A suitable core substrate 12 is selected. In some embodiments, the core substrate 12 must be capable of withstanding a high-temperature environment. In the embodiment depicted in FIG. 1, a ground plane 14 is applied over the core substrate 12. A dielectric substrate 16 separates the ground plane 14 from the conductive traces to be formed. Electrode material is deposited on the dielectric substrate 16 in what will be a trace layer 18. The electrode material may be formulated to meet the specific requirements of an exothermic reaction. In the embodiment depicted in FIG. 1, two different types of electrode material are deposited. For example, material (18a) for a first electrode (e.g., anode) may comprise platinum, and material (18b) for a second electrode (e.g., cathode) may comprise palladium or nickel, or alloys thereof. In some embodiments, a layer of isolation/trapping material, such as gold, may be deposited prior to the electrode material (not shown). A mask layer 20 is deposited over the electrode material in the trace layer 18. The mask layer 20 covers the areas where electrically conductive traces are desired, and is clear elsewhere.

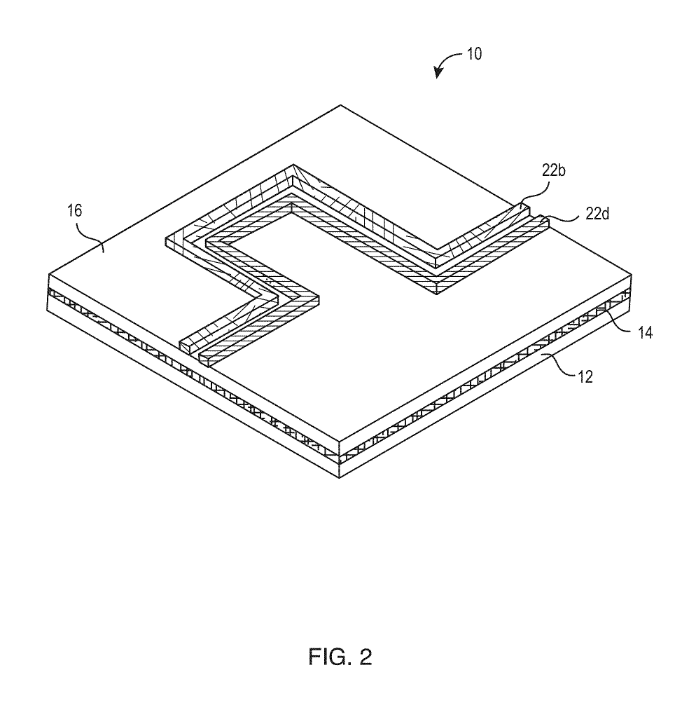

Once the stack of FIG. 1 has been built, the upper surface is etched, such as by exposure to intense light or a chemical bath. The etching process removes all exposed electrode material from the trace layer 18—that is, all electrode material other than that covered by material in the mask layer 20. FIG. 2 depicts the PCB-type exothermic reaction electrode structure 10 after the etching process is complete. First and second electrically conductive traces 22a, 22b, formed from the first and second electrode material 18a, 18b, form the first and second electrodes, respectively. In this example, both electrodes 22a, 22b are formed on the same dielectric substrate surface; in other embodiments, the electrode traces 22a, 22b may be formed on different dielectric substrate surfaces. The electrodes may comprise different materials, and are laid out in a particular size, shape, and spaced-apart relationship, as required to induce current flow between them through an interstitial medium (e.g., fluid, gas, or plasma), and/or to generate magnetic fields of desired strength and shape.

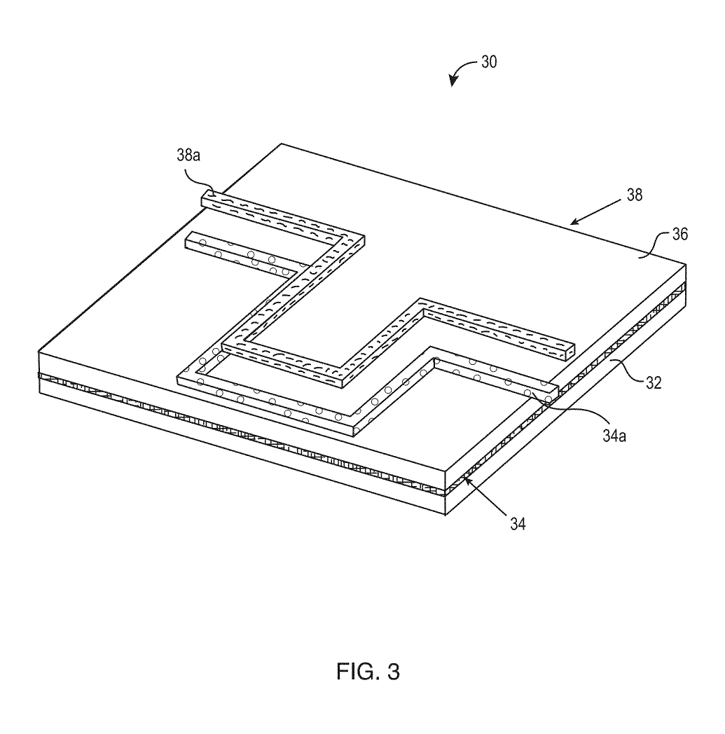

FIG. 3 depicts an embodiment of a PCB-type exothermic reaction electrode structure 30, having a core substrate 32. A first electrode trace 34a is formed on a first trace layer 34 and a second electrode trace 38a is formed on a second trace layer 38, separated by a dielectric substrate 36. That is, the first electrode 34a is formed on the core substrate surface, and the second electrode 38a is formed on a different dielectric substrate surface. This embodiment may be useful where vertical, as well as (or in lieu of) horizontal separation between the electrodes 34a, 38b is desired. The process of fabricating the PCB-type exothermic reaction electrode structure of FIG. 3 is straightforward. A first electrode material is deposited over (in this case) the core substrate 32, a mask layer is deposited over it, and an etching process is carried out to form the lower electrode 34a. A dielectric substrate 36 is then added, and the material-mask-etch process is repeated to form the second electrode 38a. As well known in the PCB arts, traces on different layers 34, 38 may be connected by vias, or holes, between the intervening dielectric substrates(s), and filled with a conductive material, such as solder (not shown) or electrode material. By utilizing multiple, possibly interconnected trace layers 34, 38, complex 3-D geometries of anode and cathode electrodes may be constructed, as required or desired for particular exothermic reaction applications.

### Wet Cell

For a typical wet cell type of exothermic reactor, a first electrode, typically made of platinum, and a second electrode, typically made of palladium or palladium alloy, are used. The first electrode is wound in a coil around the second electrode so that when voltage is applied, a magnetic field is created. The electrodes are suspended in an electrolyte, such as heavy water.

Using PCB technology to manufacture electrodes for wet cell reactors presents numerous advantages. The spacing and geometry of the first electrode with respect to the second electrode can be optimized to create a similar magnetic field when voltage is applied. The substrate can be an insulating material, such as ceramic or silicon, and the electrodes can be isolated from each other. The PCB-type exothermic reaction electrode structure can be submerged in an electrolyte, such as heavy water, that creates a path for electrons/current to flow when voltage is applied. By leveraging known lithography techniques, the robustness and capability to manufacture at high volume are improved, while still maintaining tight control over the variables that are important to exothermic reactions.

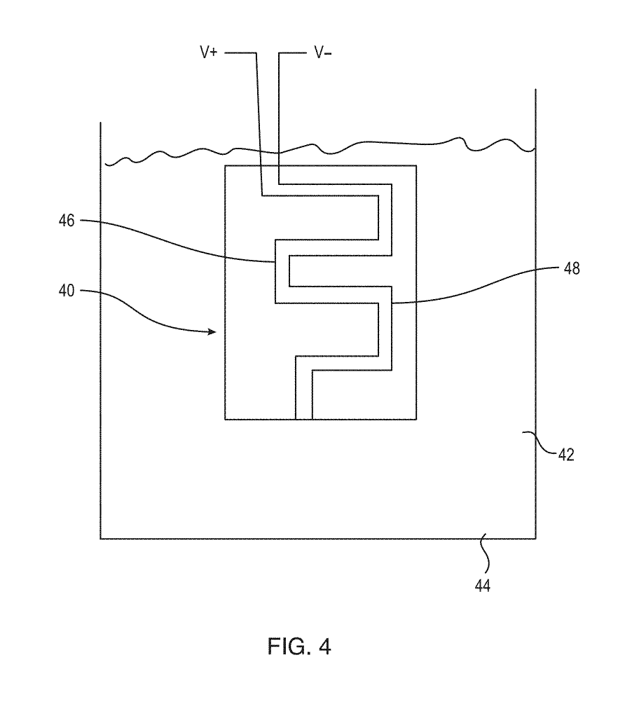

FIG. 4 depicts a PCB-type exothermic reaction electrode structure 40 in a wet cell reaction chamber. A reaction chamber 42 holds an electrolytic interstitial fluid 44, such as heavy water. The PCB-type exothermic reaction electrode structure 40, on which first and second electrode traces 46, 48—connected respectively to positive and negative electrodes of a power supply—are formed on the same dielectric substrate. The board is submerged in the electrolytic interstitial fluid 44. Voltages on the electrodes 46, 48 cause current to flow from one electrode 46 to the other electrode 48 through the electrolytic interstitial fluid 44, triggering an exothermic reaction.

### Dry/Gas Cell

For a dry/gas cell, a first electrode (e.g., the anode), typically made of platinum, tungsten, nickel, or molybdenum, and a second electrode (e.g. the cathode), typically made of palladium, palladium alloy, nickel, or nickel alloy, may be used. Alternatively, only an anode may be disposed in an exothermic reaction chamber, with the body of the chamber being grounded to serve as a cathode. In the embodiment where two electrodes are formed as a PCB-type exothermic reaction electrode structure, then depending on the desired triggering method, the first and second electrodes may have a specific relationship with one another, including their relative impedance, distance, shape, and substrate. In some embodiments, a gold layer may be plated underneath the electrode(s). The use of PCB technology is advantageous to control and standardize these relationships. A non-conductive substrate, such as silicon or ceramic, is required to force current to pass through the electrodes. The shape and distance of the traces for each electrode will allow the designer to create a desired magnetic field when a current passes through the traces. The magnetic field may act as a trigger, controlling the size and duration of the exothermic reaction.

When using PCB techniques to manufacture the electrodes, factors such as materials, impedances, and shapes can be tightly controlled, and reaction chambers of different types or shapes may be used. Leveraging lithography enables the materials and magnetic fields required for the exothermic reaction to be built at high quality and with much greater ease of manufacturing. Due to the material selection throughout, the PCB-type exothermic reaction electrode structure can withstand the rigors of an exothermic reaction environment, such as high temperature, vacuum/pressure, exposure to various reactive chemicals, and the like.

### Plasma Cell

In a conventional plasma cell exothermic reaction chamber, the inner wall of a metal cylinder may be plated with, e.g., palladium or nickel, (with, perhaps, a gold layer plated beneath it), and grounded to form a cathode. A metal anode is then suspended in the center of the cylinder, and hydrogen or deuterium gas is introduced to the chamber. A high voltage, low current signal applied to the anode creates a plasma discharge toward the cathode, accelerating H₂ or D₂ ions into the palladium lattice.

In the plasma cell embodiments of the present invention, a PCB-type exothermic reaction electrode structure may have traces of nickel and/or palladium as a first electrode and nickel as a secondary electrode. Co-deposition is viable if D₂ or H₂ is present when the traces are formed on the substrate. In some embodiments, the substrate is selected or constructed to withstand high temperatures. In the plasma cell, if vacuum, air, or gas is used between the electrodes, a flexible PCB substrate can be used to create the desired geometric shape. The PCB-type exothermic reaction electrode structure housing the electrodes may be placed in a sealed container, and the voltages are applied to the electrodes. The correct pressure and voltage would induce the plasma and eventually the exothermic reaction.

[comments indicated additional paragraphs to be inserted here describing different materials used for electrode material and an exemplary (co-)depositing processing]

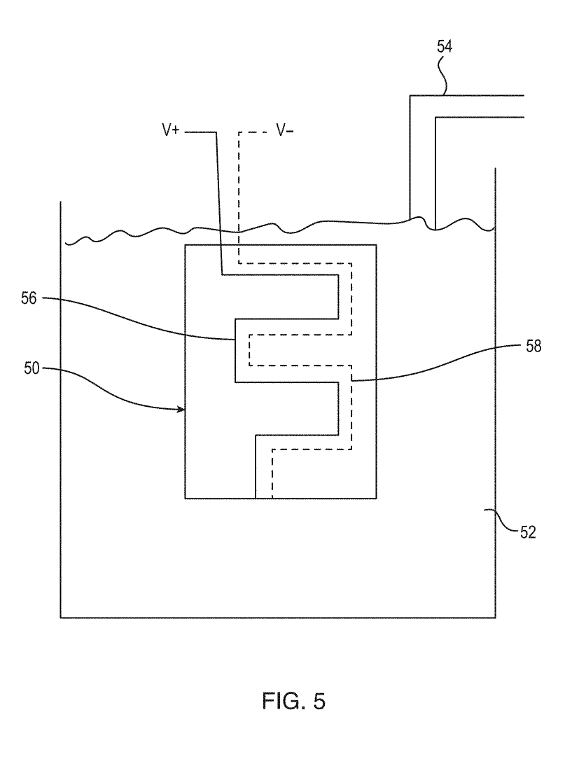

FIG. 5 depicts the use of a PCB-type exothermic reaction electrode structure 50 in a dry/gas or plasma cell exothermic reaction chamber 52. The chamber 52 is sealed, and includes at least one gas port 54 to allow drawing the interior to a vacuum, and for the introduction of hydrogen or deuterium gas. In other embodiments, additional gas ports (not shown) may be provided to produce gas flow through the chamber 52. In some embodiments, a pressure gauge, mass flow controllers, sample chambers, and the like (not shown) may be connected to the gas port 54.

The PCB-type exothermic reaction electrode structure 50 includes at least an anode trace 56, connected to the positive terminal of a power supply or signal generator. In a plasma cell embodiment, the inner wall of the reaction chamber 52 may be coated with a reactive metal such as palladium or nickel, and grounded to the negative terminal of the power supply or signal generator, forming the cathode. A plasma discharge is then generated, driving H₂ or D₂ ions from the interstitial fluid into the cathode metal lattice, preparing the cathode material for the initiation of an exothermic reaction.

In another embodiment (as indicated by dashed lines) the PCB-type exothermic reaction electrode structure 50 additionally includes a cathode trace 58, connected to the negative terminal of the power supply or signal generator. In a dry cell embodiment, voltage applied to the anode generates current flow to the cathode via ionic conduction through an interstitial gas, such as hydrogen or deuterium, preparing the cathode material for the initiation of an exothermic reaction.

### Magnetic Field Manipulation

In all of the configurations discussed above, it is believed that magnetic fields may control or influence the triggering or sustaining of exothermic reactions. In conventional exothermic reaction chambers, permanent magnets and/or electromagnets may be configured within or surrounding the reaction chamber to induce and apply the desired magnetic fields.

According to embodiments of the present invention, it is possible to use the spacing, geometry and electrical properties of electrodes formed as conductive traces on a PCB-type exothermic reaction electrode structure to generate and control magnetic fields. The desired magnetic fields can be achieved in various ways.

In one embodiment, the conductive traces are placed side-by-side on the same layer. The current flowing through the trace of a first electrode generates a magnetic field that affects the second electrode. This can further be controlled by the presence or absence of a ground plane on a different layer.

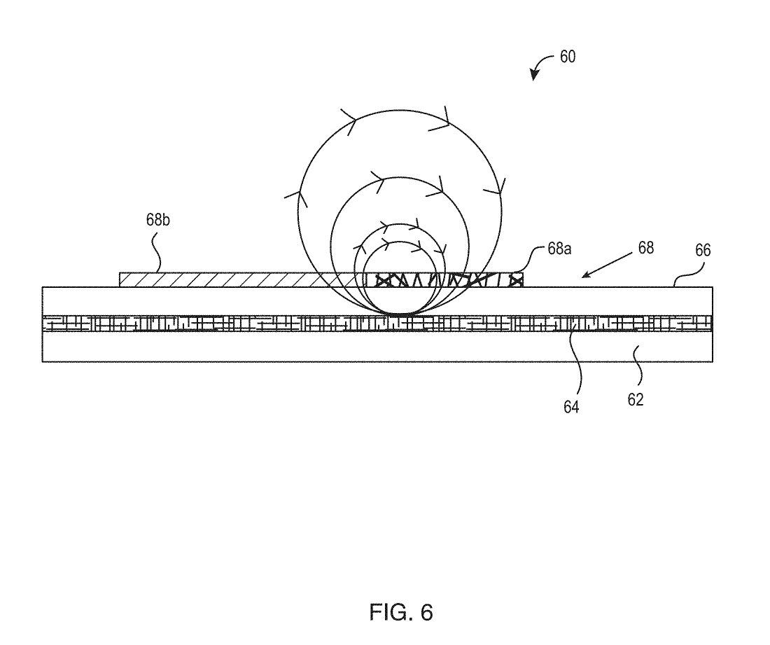

FIG. 6 depicts a PCB-type exothermic reaction electrode structure 60 having traces comprising electrode material forming a first electrode 68a and second electrode 68b side-by-side on the surface of the same dielectric substrate 68. A ground plane 64—deposed between a core substrate 62 and a dielectric substrate 66—affects the shape and strength of the magnetic field (depicted as representative magnetic flux lines).

Similar techniques and principles are used to design the placement and shape of the traces regardless of whether the PCB-type exothermic reaction electrode structure is to be deployed in a wet cell, a dry/gas cell, or a plasma cell type application. However, each type of cell may require a unique magnetic field for trigger and/or control of the exothermic reaction. This would be taken into consideration during design to determine placement and geometry of the anode and cathode traces.

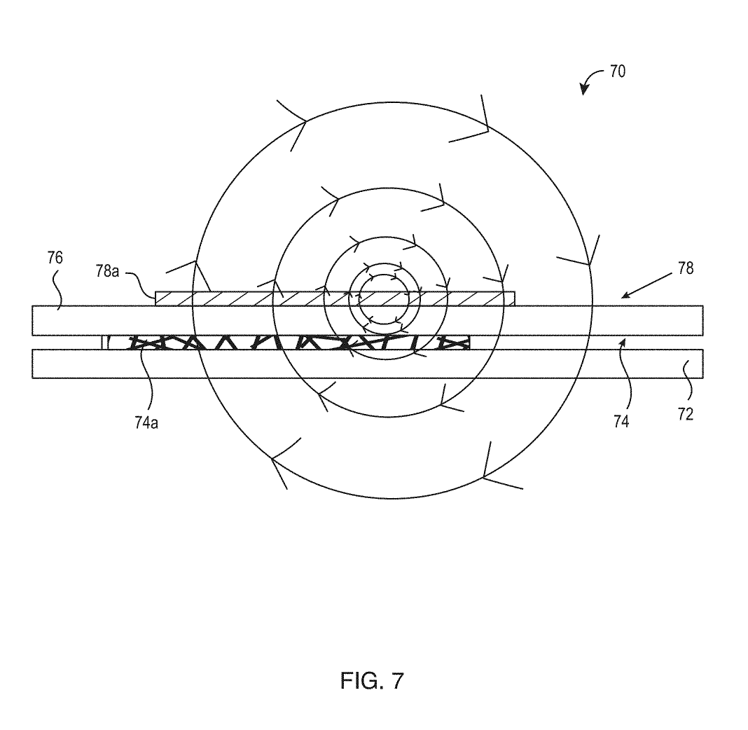

In another embodiment, the conductive traces are placed in a vertical relationship to one another, on different dielectric substrate surfaces. A substrate can be selected that allows the magnetic field to pass through with minimum attenuation or deflection. FIG. 7 depicts a PCB-type exothermic reaction electrode structure 70 having electrodes 74a, 78a formed on two trace layers 74, 78 (with a core substrate 72 below and an intervening dielectric substrage 76). Current in the uppermost electrode 78a generates a magnetic field—depicted as representative flux lines—which affects the lower electrode 74a.

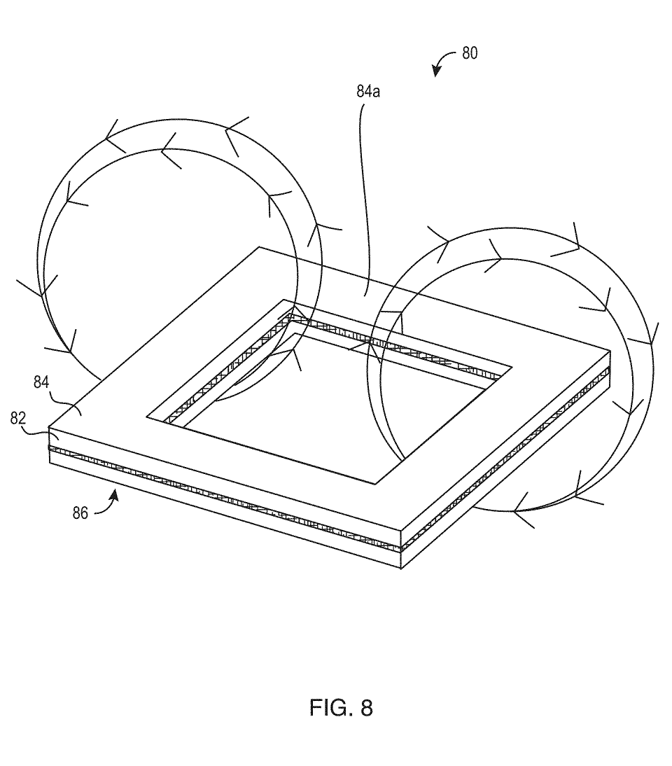

In yet another embodiment, the conductive traces are routed in a generally circular pattern, causing the magnetic field to flow perpendicularly from the board. FIG. 8 depicts a PCB-type exothermic reaction electrode structure 80 comprising a core substrate 82 with trace layers 84, 86 formed on opposing surface thereof. The electrode 84a formed on the uppermost substrate surface 84 is routed in the shape of a circular antenna, which creates a more vertical magnetic field, as depicted by the representative magnetic flux lines. This electrode 84a pattern may induce a greater effect on an electrode formed on the lower substrate surface 86.

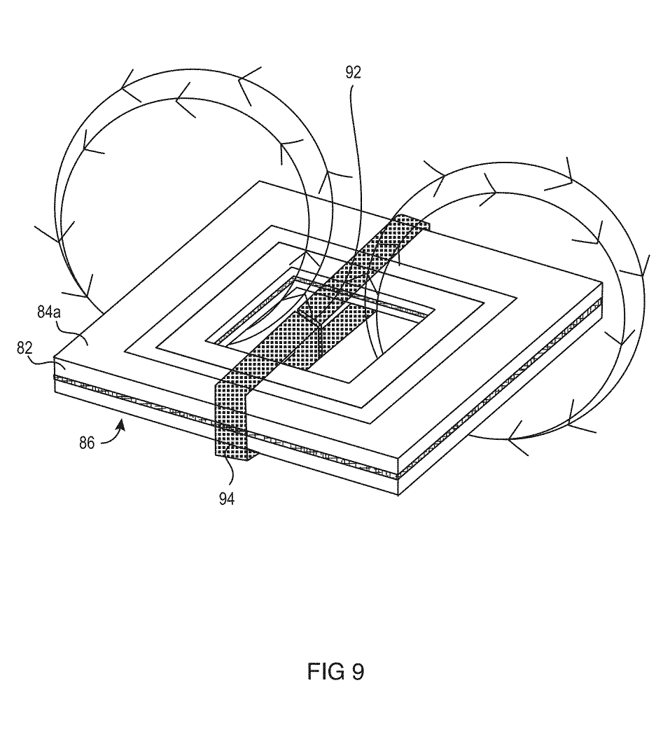

In one embodiment, a hole is formed in the board and a magnetic core inserted to amplify and/or shape the magnetic field. As known in the art, a magnetic core may be formed of any ferromagnetic material or compound. The core may be coated, to ensure that it does not contaminate the reaction. Due to the high magnetic permeability of the core, relative to the surrounding reaction chamber fluid or vacuum, magnetic flux lines are confined within the core, thus shaping the radiated magnetic field. FIG. 9 depicts the PCB-type exothermic reaction electrode structure 80 of FIG. 8, with a hole formed in the center of the circular upper electrode 84a. A magnetic core 92 may be deposed in the core. In this embodiment, a coil 94 of insulated metal wire is additionally wound around the PCB-type exothermic reaction electrode structure 80, further confining the magnetic field generated by current in the first electrode 84a.

Embodiments of the present invention present numerous advantages over known electrode formation for exothermic reactions. By applying the known techniques and technology of PCB and IC fabrication to the challenge of manufacturing electrodes for exothermic reactions, greater precision, repeatability, and manufacturability can be brought to bear, while still controlling factors such as harsh environments (e.g., with ceramic substrates) and the need for particular metal types in conductive trace formation.

Although embodiments of the present invention have been described herein with reference to PCB terminology and fabrication techniques (including the use of the phrase “PCB-type exothermic reaction electrode structure”), this is for context and ease of explanation only, and is not limiting. Those of skill in the art will recognize that semiconductor fabrication processes are substantially similar, although on a smaller scale and with greater precision (and with additional ability to alter the electrical characteristics of materials, such as by doping, ion implantation, and the like). It is currently unknown what limits, if any, the size and scale of exothermic reaction chambers and electrodes impose on the generation and sustainability of exothermic reactions. The processes may scale down to very small sizes (e.g., power sources for wristwatches or hearing aids). In such applications, semiconductor fabrication processes may be more suitable than PCB processes to the manufacture of what are referred to herein (for convenience and ease of explanation only) as “PCB-type exothermic reaction electrode structures.” Accordingly, it is stressed that PCB technology is illustrative of embodiments of the present invention only, and is not limiting. All of the features described herein—such as the formation of conductive traces on the same or different dielectric substrate surfaces; traces in various patterns; the creation and control of magnetic fields; and the like—are fully applicable to the formation of small-scale electrodes for exothermic reactions using semiconductor fabrication principles and techniques. Accordingly, features and processes depicted in the drawing figures and described herein may be readily adapted to semiconductor technology, without undue experimentation, by those of skill in the art, given the teachings of the present disclosure.

The present invention may, of course, be carried out in other ways than those specifically set forth herein without departing from essential characteristics of the invention. The present embodiments are to be considered in all respects as illustrative and not restrictive, and all changes coming within the meaning and equivalency range of the appended claims are intended to be embraced therein.

What is claimed is:

1. A PCB-type exothermic reaction electrode structure, comprising:
a core dielectric or semiconductor substrate;
a first electrode comprising a first electrode material deposited on a first dielectric or semiconductor substrate surface, the first material comprising palladium, nickel, or an alloy of palladium and nickel; and
a second substrate comprising a second electrode material deposited on a second dielectric or semiconductor substrate surface,
wherein the first and second electrodes are relatively spaced and orientated so as to create a pre-determined magnetic field when the first and second electrodes are connected to a power supply.

2. The electrode structure of claim 1, wherein the second electrode material comprises palladium, nickel, molybdenum, or tungsten.

3. The electrode structure of claim 1 wherein the first and second dielectric or semiconductor substrate surface comprise the same surface.

4. The electrode structure of claim 1 wherein the first and second dielectric or semiconductor substrate surface comprise different surfaces.

5. The electrode structure of claim 1 wherein at least one of the first and second dielectric or semiconductor substrate surfaces comprises a surface of the core substrate.

6. The electrode structure of claim 1 wherein at least one of the first and second dielectric or semiconductor substrate surface comprises a surface of a dielectric or semiconductor substrate formed over a trace layer.

7. The electrode structure of claim 1 wherein at least one of the first and second electrodes comprises electrode material deposited on two or more dielectric or semiconductor substrate surfaces and connected by vias.

8. The electrode structure of claim 1, wherein the first electrode material and the second electrode material form electrically conductive traces.

9. The electrode structure of claim 1, wherein the magnetic field is operative to trigger an exothermic reaction inside an exothermic reaction chamber in which the electrode structure is housed.

10. The electrode structure of claim 1, wherein the magnetic field is of a pre-determined magnitude and a pre-determined polarity.

11. The electrode structure of claim 1 further comprising a metal core operative to enhance or shape the magnetic field.

12. The electrode structure of claim 1 wherein the core substrate is operative to withstand temperature of at least 700° C.

13. The electrode structure of claim 12 wherein the core substrate comprises ceramic.

14. The electrode structure of claim 13 wherein the core substrate comprises zirconium.

15. A method for fabricating PCB-type exothermic reaction electrode structure, comprising:
providing a core dielectric or semiconductor substrate;
forming a first electrode as a pattern of a first electrode material comprising nickel or palladium or an alloy of nickel and palladium, the first electrode formed on a first dielectric or semiconductor substrate surface; and
forming a second electrode as a pattern of a second electrode material formed on a second dielectric or semiconductor substrate surface,
wherein the first pattern and the second pattern are relatively spaced and orientated so as to create a pre-determined magnetic field when the first and second electrodes are connected a power supply.

16. The method of claim 15, wherein forming the first electrode comprises:
depositing the first electrode material on the first dielectric or semiconductor substrate surface;
applying a mask of the first pattern over the first electrode material; and
etching away un-masked areas of the first electrode material.

17. The method of claim 15, wherein forming the first electrode comprises:
applying a mask of a negative of the first pattern over the dielectric or semiconductor layer;
depositing the first electrode material on the non-masked areas of the dielectric or semiconductor substrate surface; and
removing the mask.

18. The method of claim 15, wherein the second electrode material comprises palladium, nickel, molybdenum, or tungsten.

19. The method of claim 15, wherein the first dielectric or semiconductor substrate surface is a surface of the core substrate.

20. The method of claim 19, wherein the second dielectric or semiconductor substrate surface is an opposite surface of the core substrate than the first dielectric or semiconductor substrate surface.

21. The method of claim 15 wherein the second dielectric or semiconductor substrate surface is the same surface as the first dielectric or semiconductor substrate surface.

22. The method of claim 15 wherein the second dielectric or semiconductor substrate surface is a surface of a different substrate than that having the first dielectric or semiconductor substrate surface.

23. The method of claim 22, wherein the magnetic field is operative to trigger an exothermic reaction.

24. The method of claim 22, wherein the magnetic field is of a pre-determined magnitude and polarity.

25. An exothermic reaction chamber, comprising:
an anode connected to a first power supply terminal;
a cathode connected to a second power supply terminal;
wherein at least one of the anode and cathode comprises a first electrically conductive trace on a dielectric or semiconductor substrate; and
a housing comprising the anode, cathode, and optionally an interstitial fluid;
whereby one of a current between the anode and cathode, and a magnetic field generated by the anode, the cathode, or both, is operative to trigger or control an exothermic reaction in the exothermic reaction chamber.

26. The exothermic reaction chamber of claim 25 wherein the anode comprises the first electrically conductive trace on a dielectric or semiconductor substrate and the cathode comprises the housing or a metal or alloy plated onto the housing.

27. The exothermic reaction chamber of claim 25 wherein the anode comprises the first electrically conductive trace on a first dielectric or semiconductor substrate, and the cathode comprises a second electrically conductive trace on a different, second dielectric or semiconductor substrate.

28. The exothermic reaction chamber of claim 27 wherein the anode comprises the first electrically conductive trace on a dielectric or semiconductor substrate, and the cathode comprises a second electrically conductive trace on the same dielectric or semiconductor substrate.

29. The exothermic reaction chamber of claim 28 wherein the anode and cathode are formed on different layers of the same dielectric or semiconductor substrate.

30. The exothermic reaction chamber of claim 28 wherein at least one of the anode and cathode comprise electrically conductive traces formed on a plurality of different layers of the same dielectric or semiconductor substrate, the conductive traces on different layers electrically connected between layers by conductive vias.

31. The exothermic reaction chamber of claim 28 wherein one of the anode and cathode electrically conductive traces are shaped to enhance a magnetic field generated when electrical current flows through the conductive traces.

32. The exothermic reaction chamber of claim 31 further comprising a ground plane on the dielectric or semiconductor substrate.

33. The exothermic reaction chamber of claim 32 further comprising a metal core affixed to the dielectric or semiconductor substrate and operative to enhance or shape the magnetic field.

34. The exothermic reaction chamber of claim 25 wherein the dielectric or semiconductor substrate is operative to withstand temperature of at least 700° C.

35. The exothermic reaction chamber of claim 34 wherein the dielectric or semiconductor substrate comprises ceramic.

36. The exothermic reaction chamber of claim 34 wherein the dielectric or semiconductor substrate comprises zirconium.

37. The exothermic reaction chamber of claim 25 wherein the first electrically conductive trace is formed from platinum.

38. The exothermic reaction chamber of claim 27 wherein the second electrically conductive trace is formed from palladium or nickel.
